(19) United States
(12) Patent Application Publication
(10) Pub. No.: US 2009/0228760 A1
(43) Pub. Date: Sep. 10, 2009

(54) Robust and efficient communications systems apparatus using Koay-Vaman transform technique to handle burst noise

(76) Inventor: Dhadesugoor Vaman, Spring, TX (US)

Correspondence Address: DHADESUGOOR R. VAMAN, 10511 FLAXEN MANOR COURT, SPRING, TX, 77379, US

(21) Appl. No.: 12/074,905

(22) Filed: Mar. 8, 2008

(51) Int. Cl. H03M 13/00

(52) U.S. Cl. 714/761; 714/E11.001

(57) ABSTRACT

The proposed invention teaches the principle of KV transform coding is an orthogonal and invertible “embedded transform coding” method that provides a very efficient error control with low-complexity decoding and operates at very low Eb/N0. It is unique in the sense that it corrects errors and the remaining samples in error are known unlike other known techniques. The proposed invention has been implemented with error correction, single retransmission of selected samples in error and interleaving of samples of KV blocks to achieve BER of 10⁻⁷ at average EB/N0 of <10 dB and BER of 10⁻³ at an average BER of <3 dB. More over, the proposed system has a code redundancy of log₂ (n) for correcting first order correction of one sample in error out of four samples received with a code rate of 2/3. The invention is useful for noisy wireless networks.

### I. BACKGROUND OF THE INVENTION

This patent teaches a novel method of block transform coding technique called “Koay-Vaman (KV) Transform Coding” for correcting errors in very bursty channels. Many communications systems including Telephone Networks, Satellite Networks, Terrestrial Networks, Wireless Networks, Mobile Ad Hoc Networks (MANET) and Sensor Networks exhibit poor Signal to Noise Ratio (SNR) or Energy/bit over Noise (commonly referred to as Eb/N0). The communications media in these networks exhibits varieties of noise ranging from typical burst noise over time, multi-path interference and Doppler spread and Additive White Gaussian Noise (AWGN). Existing systems tend to use retransmission techniques which often increase the response time to deliver information from one end to other, there by provisioning Quality of Service (QoS) assurance for end user applications is very difficult. Specifically, MANETs and Sensor Networks user peer-peer multi-hop radio communications and experience significant multi-path interference in both indoor and outdoor environment. Both of these networks are infrastructure less, highly mobile and path connectivity has to be maintained by dynamic switching of paths without loss of information; and each radio transmit information with severe power limitation. Most of these systems require recovery of information at very low Eb/N0 (<10 dB) during severe interference which can occur both outdoor and heavily fortified indoor environments.

The proposed invention teacher the principle of KV transform coding is an orthogonal and invertible “embedded transform coding” method that provides a very efficient error control with low-complexity decoding and operates at very low Eb/N0, thus offer a significant opportunity to handle multi-path interference. KV transform operates on a set of discrete samples and produce a set discrete coefficient samples. In addition, it produces discrete overhead samples that can be used at the receiving side for correcting one out of four samples in error exactly. In addition, since it can detect any selected block of samples where errors cannot be corrected will provide the ability to have a single selected retransmission to improve the performance at very low average Eb/N0. Although the discrete values of each coefficient is in an infinite field, the modified samples for retransmission have equal number of discrete values and therefore can be coded by a finite size of binary data. The proposed scheme employs creating a discrete sample with 5 bits of input data from the source and developing the coefficient samples and overhead samples to each coded by 5 bits. This transform coding is a major departure from traditional block coding design paradigm in which the fields of finite order (cardinality) GF(q) are particularly interesting to coding theorist. But in the case of KV transform coding, the relative simplicity in decoding enables achieving very low probability of undetected errors while using first order correction of one sample out of four samples in error; using single retransmission of a particular block; and sample dispersion to handle multi-path interference at very low average Eb/N0.

The proposed invention also teaches how KV transform performs and it has been compared with simple 32-ary PAM system for the purpose of understanding. The performance of KV/32-ary PAM with first order correction of one sample out of four samples in error; using single retransmission of a particular block; and sample dispersion is compared with the conventional 32-ary, 16-ary and 8-ary PAM system. The simulation of real time KV system shows that the proposed KV system achieves BER of 10⁻⁷ at average EB/N0 of <10 dB and BER of 10⁻³ at an average BER of <3 dB. More over, the proposed system has a code redundancy of log₂ (n) for correcting first order correction of one sample in error out of four samples received with a code rate of 2/3.

Although, the teaching is based on using 5 bits of user information/sample and use four samples as input to KV transform to produce four coefficient samples and two overhead samples, the teaching does not preclude having n samples as input and producing n coefficient samples and m overhead samples to allow the receiving side to correct n/2 coefficient samples in error out of n coefficient samples.

The proposed teaching also demonstrates the very low complexity of recovering information at the receiver which allows it to be well adapted in low power devices or radios where processing has to be very quick to save the power which otherwise not achievable with high complex decoders which use other types of conventional techniques such as Reed-Solomon Coding or Hadamard Coding.
1. Commercial applications include “sensor networks being deployed in urban areas for monitoring traffic on the roads, toll collection methods, Urban building security apparatus’.
2. Military applications include battlefield communications using MANET and sensors for handling terrorism, enemy combat identification.
3. Data Fusion nodes in sensor networks where the received data messages coded by KV transform can be intentionally dropped to accommodate more users on the output side and recover the dropped messages at the destinations.
4. Any system or network where congestion needs to be handled, some message units coded by KV can be dropped and they can be recovered at the destination.

### II. BRIEF SUMMARY OF THE INVENTION

II. A. Background

Error detection techniques have been widely used in network centric architectures. Predominantly, the Cyclic Redundancy Check (CRC) has been used in different layers, where the messages are sent from the transmit side with the CRC data to a remote receive side. At the receiving side, the CRC is used to detect errors. CRC allows the detection of errors and does not have any knowledge of the location of errors. Therefore, for successful transmission of messages, it is important to request retransmission of the same messages until they are received correctly at the receiving side. While this technique reduces the undetected errors in the messages, the penalty in the network is the increased delay and thereby response time to the end user that affects the Quality of Service (QoS). In Mobile Ad Hoc Networks (MANETs), if this technique is used at the link layer, the overall throughput is significantly reduced. Also, if link by link is used for error handling in a multi-hop connected path, there is a significant increase in end-to-end delay significantly [1].

On the other hand, Forward Error Correction (FEC) has been used widely in many satellite and wireless channels. FEC technique typically allows sending a separate error correcting code with the messages and at the receiving side the errors in the messages are corrected with the error correcting code using different statistical principles. Therefore, the undetected error rate in the messages is minimized. Since, FEC techniques tend to use statistical properties, the processing delay at the receiving side actually increases. Also, they tend to correct errors, but cannot know the location of remaining errors. Thus, the system cannot use any second order error correction. Typical coding techniques such as Reed-Solomon code have more complexity in the decoding process. The power of processing increases significantly. The overhead percentage is a function of the channel errors and therefore is difficult to be used in MANETs. Many FEC techniques have been described significantly by many researchers [2, 3, 4]. These techniques can detect and correct errors, but they cannot detect the location of remaining errors and therefore, the remaining errors are passed to the next layer of the protocol as undetected errors.

In MANETs, all of the above error detection and retransmission techniques; and forward error correction techniques tend to increase the overall processing time and also overhead. These techniques affect the provisioning of QoS and tend to increase the overhead bandwidth used in the network. Also, the undetected error rates tend to increase statistically as the channel noise is increased.

Embedded transform coding techniques can be classified as FEC techniques with the exception that they are based on transform technique, where the user data is transformed and sent to the receiving side. The transformation allows for error correction with some side information. These techniques have been used extensively in image processing applications [5, 6]. However, to the best of our knowledge, they have not been used for error correction in network centric architectures as part of the transport system. In this paper, the proposed KV transform technique, which is in the class of embedded transform coding, is demonstrated for correcting errors at very low Eb/N0. The simulation of real time KV system shows that the proposed KV system achieves BER of 10⁻⁷ at an average Eb/N0 of <10 dB and BER of 10⁻³ at an average BER of <3 dB.

There are two motives for designing KV Transform coding technique:
1. The recovery of data at low Eb/N0 which occurs typically in Wireless Networks due to multi-path interference.
2. Achieving error correction at the physical layer using KV transform at low Eb/N0 enables higher layer protocols such as Transport Control Protocol (TCP) and lower layer protocols such as Medium Access Control (MAC) not increase the bandwidth inefficiency due to excessive retransmissions.

In the proposed teaching, we describe the KV transform technique, which is in the class of embedded transform coding and demonstrate its novel method of correcting errors at very low Eb/N0. The teaching has been implemented in real time emulation environment to verify the performance of the proposed KV transform technique.

II. B. KV Transform Technique

KV transform is a method of designing a set of “orthogonal basis functions” and they are used to transform a set of discrete input samples into a set of coefficient samples. The discrete input samples are created by using a set of digital bits (n=5 is used for the implemented system) from an input source. The coefficient samples are sent to the receiving side. Since the transform is invertible, the receiving side will estimate the discrete input samples and then recover the data bits. The KV transform technique also creates overhead samples for error correction where one out of four samples is corrected. This technique has the following unique properties:
1. It takes the source information in digital form and creates a set of discrete samples with n bits per sample. In the proposed implemented system, n=5 bits and four samples are created as input to the KV transform coding.
2. It uses orthogonal transformation of the input samples using a set of basis vectors and generates four coefficient samples and two overhead samples for error correction.
3. The receiving side receives coefficient samples and overhead samples and corrects one sample out of four samples exactly. It also identifies the block where it cannot correct errors. This allows taking secondary actions to improve the performance. In the proposed system, one selective retransmission of the KV block that could not be corrected for errors has been used. That is, the sending side will be asked to send the selected block in the next transmission cycle. Thus, while it improves the performance, there is an additional one transmission cycle delay which is very small.
4. The system also has the sample interleaving property, where multiple KV blocks process the input samples in parallel and allow sample interleaving where the first samples of each KV block is sent in the first message block, the second samples of each KV block is sent in the second message block and so on. The sample interleaving significantly improve the performance of the KV system at low average Eb/No (<10 dB) to achieve Bit Error Rates of the order of 10⁻⁷, thus minimizing the impact of burst errors.
5. The KV transform can be used above the transport layer or at the physical layer. The performance of the system is the same in both implementations. However, when KV transform is used above the transport layer, the system cannot improve the performance of TCP/IP protocol, but will improve the performance when using UDP/IP protocol. When it is used at the physical layer, all higher layer functions remain the same and therefore the link layer performance and the TCP performance will be significantly boosted since the errors are corrected right at the physical layer.

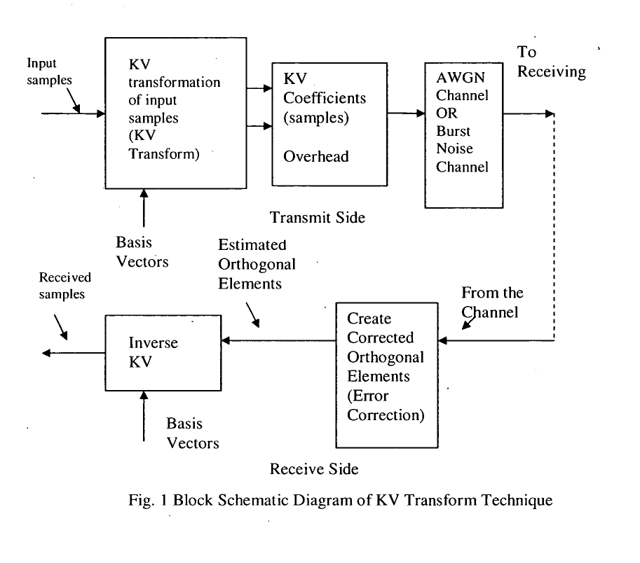

FIG. 1 illustrates the basic block diagram of the communications system using KV transform technique. These blocks form the IP payload and the transmission uses the IP protocol. As illustrated in FIG. 1, the input samples are transformed into KV coefficient samples using basis function. The number of KV coefficient samples generated is equal to the number of input samples. Assuming that there are n input samples in a vector with n being 4, 8, 16, 32, . . . , it is possible to define a set of n orthogonal basis functions (or vector) with each one consisting of n samples (or input vector). The dot product of the input vector with each one of the orthogonal basis vector generates n KV coefficient samples. These KV coefficient samples are then transmitted to the receiver. Because of invertibility, each KV coefficient sample is multiplied with the normalized orthogonal basis functions to estimate the n vectors. The sum of the elements in each vector is the estimate of each input sample. When coefficient samples are received in error, they have to be corrected prior to inverse operation.

Appendix A illustrates the mathematical description of the KV transform technique. While the proposed KV system implementation in this paper only uses 5 bits/discrete input sample and use four samples as input to the KV transform on the sending side to produce four coefficient samples and two overhead samples, the KV transform technique is applicable to any bits/sample and any number of samples as input to the KV transform coder.

### III. BRIEF DESCRIPTION OF THE DRAWINGS

FIG. 1 Block Schematic Diagram of KV Transform Technique
Illustrates the basic operation of the Invention.

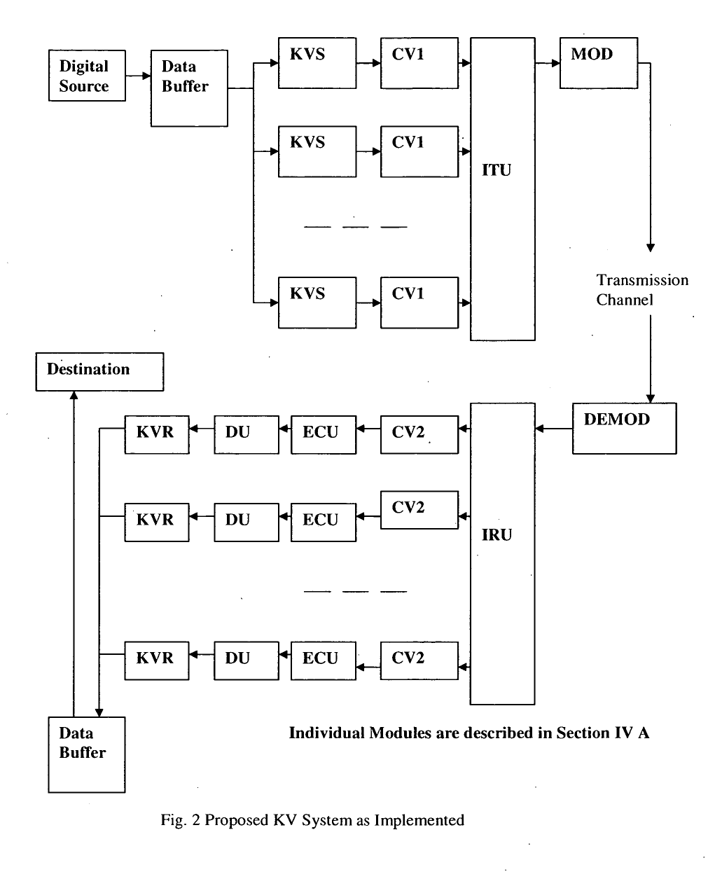

FIG. 2 Proposed KV System as Implemented
Proposed Invention was implemented for Verification of Performance.

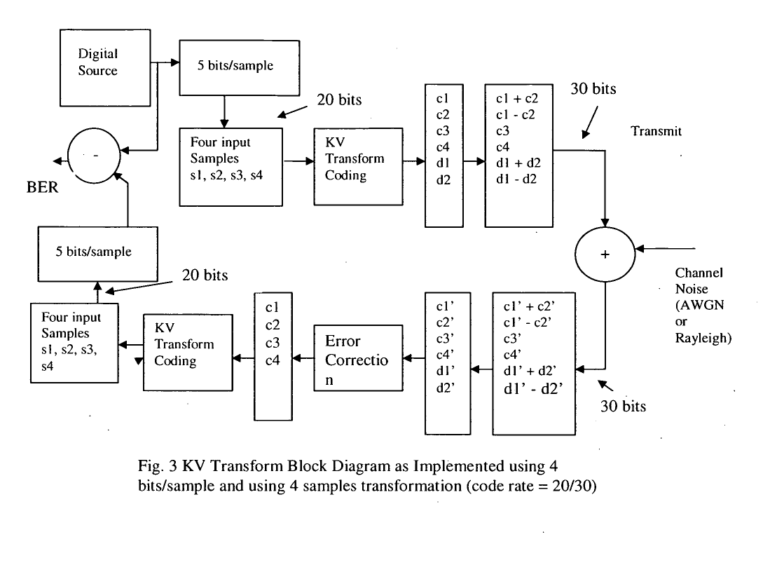

FIG. 3 KV Transform Block Diagram as implemented using 4 bits/sample and using 4 samples transformation (code rate=20/30)
Actual Implementation is provided in detail

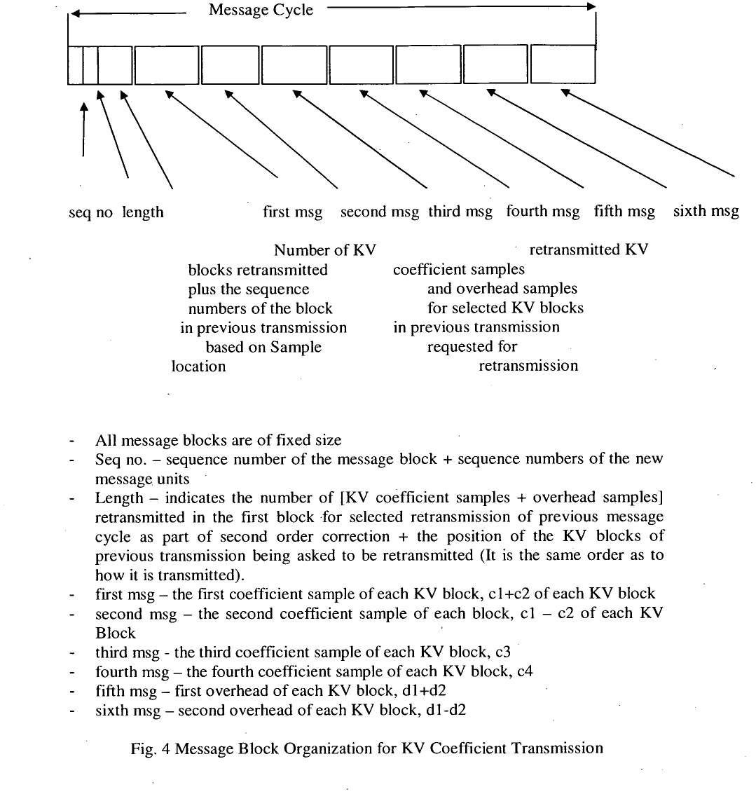

FIG. 4 Message Block Organization for KV Coefficient Transmission
Transmission Format that takes into account of selected single retransmission.

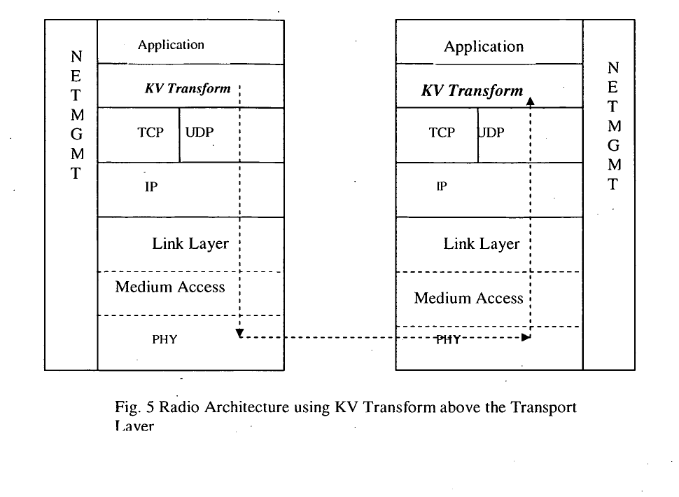

FIG. 5 Radio Architecture using KV Transform above the Transport Layer
Illustrates high level architecture of a software configurable radio with KV transform above the transport layer of OSI.

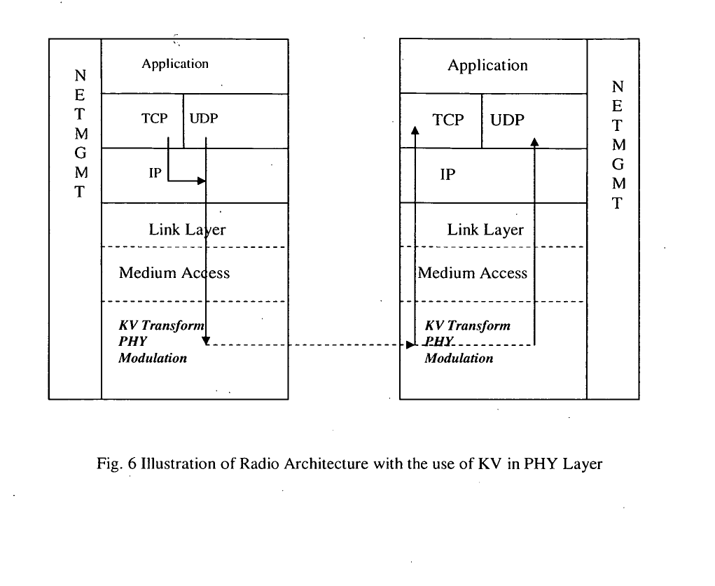

FIG. 6 Illustration of Radio Architecture with the use of KV in PHY Layer
Illustrates high level architecture of a software configurable radio with KV transform at the physical layer of OSI.

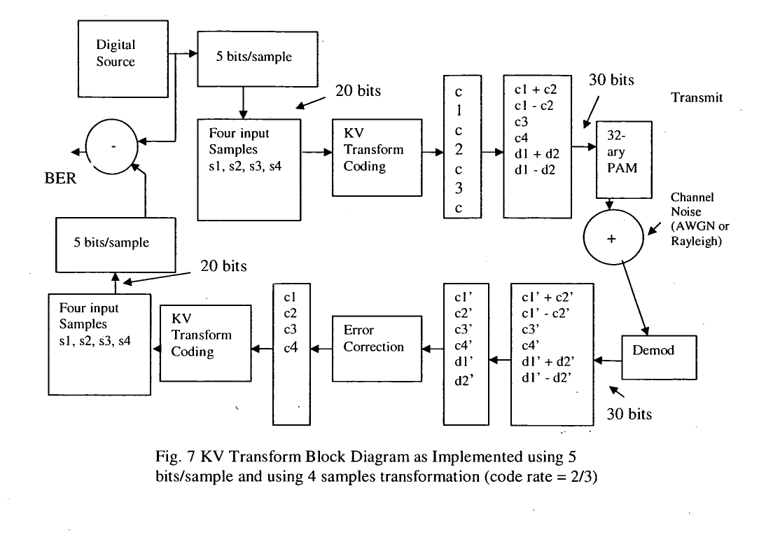

FIG. 7 KV Transform Block Diagram as Implemented using 5 bits/sample and using 4 samples transformation (code rate=2/3)
Illustration of KV with PAM Modulation.

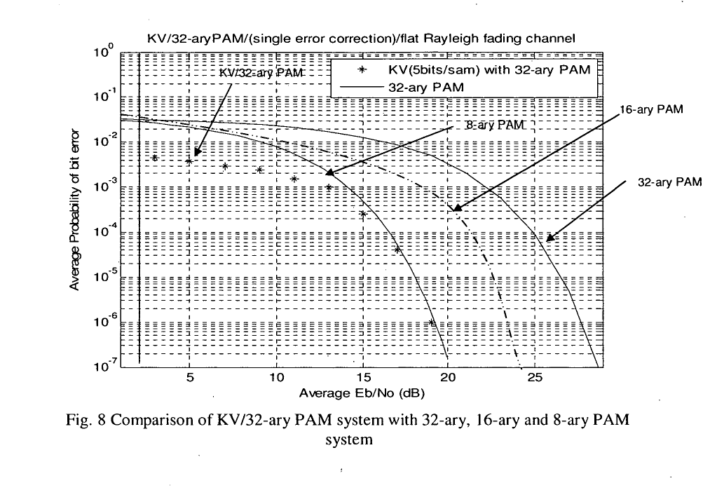

FIG. 8 Comparison of KV/32-ary PAM system with 32-ary, 16-ary and 8-ary PAM system
Performance measured for comparison.

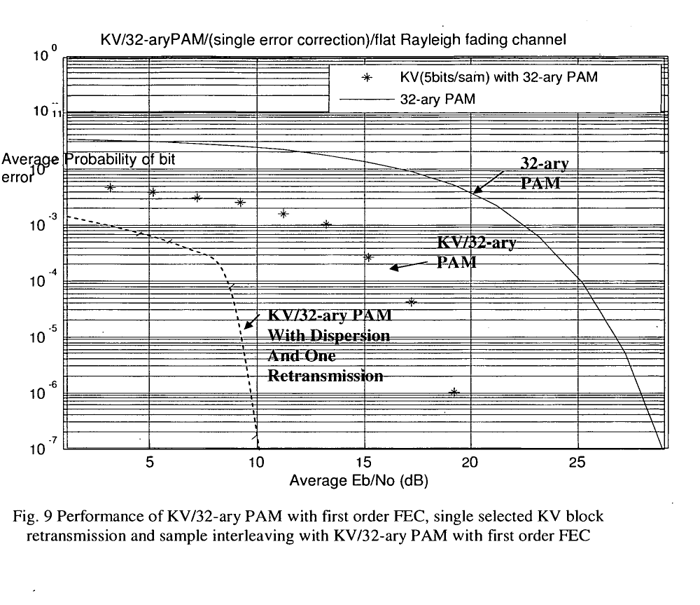

FIG. 9 Performance of KV/32-ary PAM with first order FEC, single selected KV block retransmission and sample interleaving with KV/32-ary PAM with first order FEC
Enhanced performance of KV with single selected retransmission and interleaving of samples.

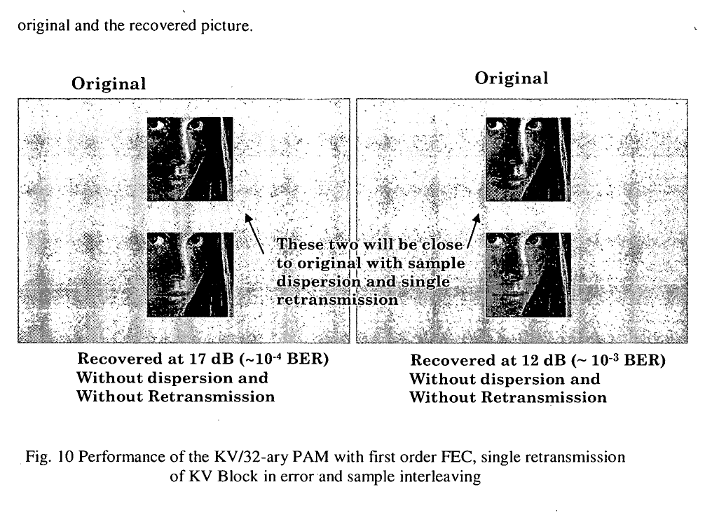

FIG. 10 Performance of the KV/32-ary PAM with first order FEC, single retransmission of KV Block in error and sample interleaving
Transmitted JPEG for performance comparison.

### IV. DETAILED DESCRIPTION OF THE INVENTION

IV. A. Proposed KV System Implementation

The proposed KV system has been implemented and its performance has been demonstrated as discussed later using the following modules implemented in the KV System:
KV Transform Coder at the Sending side (KVS) that takes four discrete samples (A) and produces four orthogonal coefficient samples, c1, c2, c3, c4 (B) and two overhead samples d1 and d2 (C).
Converter unit 1 (CV1) at the sending side which takes (B) and (C) and convert into four transmission samples, c1+c2, c1−c2, c3, c4 and d1+d2 and d1−d2 (D).
Interleaving Transmitting Unit (ITU) at the sending side takes the samples (D) from each of the M (64 and 128 blocks have been implemented) KV Blocks and forms six message units (K) as described earlier. Each sample has 5 digits to represent 32 unique discrete values in each sample of the message unit.
32-ary Pulse Amplitude Modulator (PAM)-(MOD): Each sample is modulated in a transmission cycle by 32-ary PAM and is sent to the receiver.
32-ary Pulse Amplitude Demodulator (DEMOD): The PAM at the receiving side demodulates and recovers each sample in the message unit (R).
Interleaving Receive Unit (IRU) at the receiving side groups appropriate samples of each KV block from (R) and sends the sample groups (G) to the converter unit for each KV block.
Converter unit 2 (CV2) at the receiving side converts the samples (G) into samples (B) and (C).
Error Correction Unit (ECU) for each group uses (B) and (C) to check for errors in samples in (B) and corrects the samples to recover c1, c2, c3 and c4 (E).
Decision Unit (DU) determines whether (E) has all correct samples or it has errors in samples. Note that the Error Correction Unit only corrects one sample in error out of four samples. If more than one sample (2, 3 and 4) is in error out of four, then it declares that the received samples are not correctable.
   If all samples are correct, then it will allow the samples (E) to go to the Inverse KV Transform Decoder.
   Otherwise, it set the KV Block that is in error for one and only retransmission.
Inverse KV Transform Coding Technique at the receiving side (KVR) that takes four received coefficient samples after correction and estimates the discrete inputs samples (A).

FIG. 2 illustrates the implemented KV System Block Diagram.

IV. B. Error Correcting Technique

The proposed KV system implements two layers of error correction technique:
a. Forward Error Correction (FEC) Technique
b. Block Transmission of KV Blocks and Permit Single Retransmission of each KV Block when the samples are not correctable.

Before illustrating the above aspects of error correction, we considered the interleaving of samples, where M KV Blocks are used in parallel, where each KV block produces six samples for transmission transforming four input samples. Thus, each KV block requires transmission of six samples, c1+c2, c1−c2, c3, c4, and d1+d2, d1−d2. Using this configuration it is possible to interleave the transmission samples by transmitting six message units to the receiver where:
The first message unit transmits the first sample, c1+c2 from each KV block
The second message unit transmits the second sample, c1−c2 from each KV block
The third message unit transmits the third sample, c3 of each KV block.
The fourth message unit transmits the fourth sample, c4 of each KV block.
The fifth message unit transmits the fifth sample, d1+d2 of each KV block.
The sixth message unit transmits the sixth sample, d1−d2 of each KV block.

When M KV blocks are used, each message unit consists of M samples. Thus, in each message cycle, there are six message units are transmitted each consisting of M samples. In this method of interleaving, the coefficient samples of each KV block are separated by M samples rather than transmitting in sequence. The intent is to minimize the impact of multi-path fading [7, 8].

If we visualize sending six samples of each KV block sequentially in a Rayleigh faded channel that represents the multi-path, it can be shown by using the convergence principle of the Central Limit theorem that by using interleaving (as shown above) in each message cycle with M>64, the samples of each KV block appears to be impacted on the channel by AWGN instead of Rayleigh. For our system, we have chosen M as 64 or 128. When M=64, there is still a finite probability that there is an impact of burst errors.

However, when M KV blocks are used to process the input samples, there is a need to buffer the input samples prior to using KV transformation. In this case, each KV block has four input samples with each input sample carrying 5 bits. That is each KV block processes 20 bits. The buffer size for 64 KV blocks would be 1280 bits and for 128 blocks it is 2560 bits.

For VOIP application, the data is being received at a rate 64 kbit/s, therefore the buffer generation time is 20 ms and 40 ms for buffer size of 1280 bits and 2560 bits respectively.

For transmission, we need to consider the transmission of 6 message units instead of 4 message units since we send two overhead samples for each four coefficient samples. Therefore the required transmission rate is 96 kbit/s. For message unit sizes of 64 and 128 samples, the equivalent number of bits to be transmitted is equal to 320 bits (or 64×5 bits) and 640 bits (128×5 bits). The transmission time (at the transmission rate=96 kbit/s) for the message units for sizes of 64 and 128 samples is 3.33 ms and 6.66 ms respectively. Since we transmit 6 samples for each KV block, these values corresponds to 20 ms and 40 ms of buffer generation times respectively.

At the receiving side, the received samples of each KV block are separated from the interleaved message units. They are corrected using the FEC technique and the corrected samples are used as input to the corresponding inverse KV transform to estimate the input samples to recover the end user data.

Obviously for video and data applications, one can increase the number of KV blocks and therefore create much larger buffer size.

IV.B.1 Forward Error Correction (FEC) Technique

From FIG. 3, we assume that each sending side KV block transmits c1+c2, c1−c2, c3, c4, d1+d2, d1−d2 and the corresponding receiving side KV block receives c1′+c2′, c1′−c2′, c3′, c4′, d1′+d2′ and d1′−d2′ after the channel noise is added. From these received samples, c1′ and c2′ are computed using c1′+c1′ and c1′−c2′. Similarly, d1′ and d2′ are computed using d1′+d2′ and d1′−d2′.

With this we have c1′, c2′, c3′ c4′, d1′, d2′ as the samples at the input to the inverse KV transform in the receiver side. Now we construct:

d1=c1′+c2′+c4′

d2=c1′−c2′+c3′

Since we know the received values of d1′ and d2′, we now construct the following difference information:

Δ1=d1−d1′

Δ2=d2−d2′

Using these two difference information, we identify the location of the error in terms of which coefficient sample has error.

1. IF Δ1 and Δ2 are both Zero:

THEN, there are no errors in any of the received coefficient samples.

2. IF Δ1 and Δ2 both increase OR decrease by the same amount, X

THEN coefficient sample c1 is in error.
Then SUBTRACT or ADD X to d1 and d2 to compute the correct value of c1.

3. IF Δ1 increases AND Δ2 decreases by the same amount, X

THEN coefficient sample c2 is in error.
Then SUBTRACT X from d1 and ADD X to d2 and compute the correct value of c2.

4. IF Δ1=ZERO and Δ2≠ZERO (no error),

THEN, c3 has error
IF Δ2 is <0, the received value d2′ is greater than the computed value by an amount X.
   SUBTRACT X from c3′ to correct it.
IF Δ2 is >0, the received value d2′ is less than the computed value by an amount X.
   ADD X to c3′ to correct it.

5. IF Δ1≠ZERO (no error) and Δ2=ZERO,

THEN, c4 has error
IF Δ1 is <0, the received value d1′ is greater than the computed value by an amount X.
   SUBTRACT X from c4′ to correct it.
IF Δ1 is >0, the received value d1′ is less than the computed value by an amount X.
   ADD X to c4′ to correct it.

6. If Δ1 and Δ2 do not satisfy the above 5 sets, then the KV block cannot be corrected and therefore needs to be retransmitted. This condition can occur if d1′, d2′ are received in error or more than one coefficient sample out of four are received in error.

IV.B.2 Block Transmission of KV Blocks and Permit Single Retransmission of Each KV Block When the Samples are not Correctable

When the coefficient and overhead samples are received at the receiver, there are three conditions that are likely to occur:
All samples are received correctly
One of four coefficient samples is received in error
Greater than or equal to two out of four samples are in error or the overhead samples are received in error.

The last condition has four possible events: two out of four: two out of four, three out of four and four out of four samples are in error; and any overhead sample is in error. The other two conditions pertain to only two events. At low average Bit Energy/Noise (Eb/N0), the probability of the third condition is higher. However, the probability decreases for higher Eb/N0. If the sample dispersion is used, the probability of occurrence of the third condition is further reduced.

In Section 2.2.1, it has been shown that the error correction procedure corrects one coefficient sample in error out of four sample coefficients in each block exactly. Also, when errors are not correctable, it is possible to identify which KV block is not correctable and therefore it can be retransmitted selectively in the next transmission cycle. In our proposed implementation, we only allow one selective retransmission of a KV block that could not be corrected. It increases the transmission delay of one cycle. FIG. 4 illustrates the transmission format for achieving the single retransmission of selected KV blocks in error and interleaving of coefficient and overhead samples. The performance of first order correction with selective retransmission for second order correction and sample interleaving is discussed in Section 4.

IV.C. Radio Architectures Using KV Transform Technique

Many researchers assume that the core transport system in Mobile Ad Hoc Networks (MANETs) is based on Internet Protocol (IP) as the seamless protocol in order to exploit many existing end user multi-service applications. The radio architectures proposed in this paper with the implementation of KV transform are consistent with the ISO reference model. We assume that the scalable MANET architecture is based on using a set of clusters with a cluster head and allows peer-to-peer communications using multi-hop path connectivity within each cluster [vaman's paper]. The number of hops is determined by many other aspects including power control and desired Quality of Service (QoS) for applications [9, 10]. The use of KV transform is to enable end-to-end correction of up to 25% of sample errors without retransmission. There are two ways KV transform can be implemented in a radio:
KV Transform coding implemented above the transport layer
KV Transform coding implemented at the physical layer

When using KV transform coding above the transport layer (as shown in FIG. 5), TCP protocol cannot take advantage of the error correction property of the KV transform coding and therefore, any bandwidth inefficiency of TCP due to end-to-end retransmission cannot be reduced. Thus, when using KV transform coding above the transport layer, applications (such as Voice/IP) using UDP protocol can benefit from the error correction ability of the KV transform coding. Applications that use TCP/IP must have some other error correction strategy at lower layers. However, conventional methods such as error detection strategies at link layers tend to be too slow since they are link-by-link based. In multi-hop peer-to-peer MANETs, the use of these conventional link-by-link basis error detection and retransmission procedures tend to be too slow and the end-to-end response times increase and therefore they cannot be used. By and large, it is a common understanding that the use of TCP/IP based applications is not going to be efficient in MANET.

Also, in this architecture, the input information to KV transform comes from the application messages which are typically in digital form. Since KV transform uses 6 samples to be transmitted for every 4 input samples, the code rate of KV is 2/3 and it corrects one error sample received out of four sample errors. It is expected that the single retransmission of KV block further improves the performance. Also, the processing delay including the error correction and transmission is constant irrespective of the channel noise. Typical error handling is done at the link layer using retransmission tends to increase the system delay exponentially.

The second architectural alternative is to use KV transform technique at the physical layer along with the modulation scheme as shown in FIG. 6. Therefore, all error corrections are completed at the Physical Layer and higher layer protocols of the radio are maintained for applications as is.

In this architecture, discrete samples are created by using n bits (where n=1, 2, 3, 4, 5, 6 . . . ) of the MAC frame or link layer.

The performance of KV remains the same whether it is placed above the transport layer or at the physical layer.

IV.D. KV System Performance

In this paper, we proposed to use a basic modulation technique, Pulse Amplitude Modulation (PAM) [11, 12, 13]. Since each transmitted KV sample can be coded discretely with 5 bits, we choose 32-ary PAM. In this Section, the performance of KV/32-ary PAM system is compared with a conventional 32-ary PAM without KV. FIG. 7 shows the system set up for performance comparison. It is possible to use more efficient digital modulation techniques for KV, but it is beyond the scope of this paper. In a conventional 32-ary PAM system, all the samples are transmitted directly without KV and have no error correction capability. In 6 transmission cycles, 32-ary PAM can transmit 30 user data bits while, KV/32-ary PAM system can transmit 20 user data bits in the same 6 transmission cycles. But its overall performance is better in terms of system delay and error handling overall. Typical 32-PAM systems need to use some form of retransmission procedures at higher layers and tend to use up the bandwidth for retransmission particularly at very low Eb/N0.

We simulated the conventional 32-ary PAM and KV/32-ary PAM system using MATLAB. We have compared the two systems using both AWGN channel and Rayleigh channel. FIG. 8 illustrates the comparison of performance of KV/32-ary PAM system with the conventional 32-ary PAM; 16-ary PAM and 8-ary PAM system in terms of Average Bit Error Rate (Av BER) versus Average Eb/N0. It can be seen at low average Eb/N0 (<15 dB), KV/32-ary PAM system performance better than the 8-ary PAM system in terms of BER. The one sample error correction of KV improves the performance over the conventional M-ary PAM systems.

FIG. 9 illustrates the performance of first order one sample out of four sample correction (FEC) and selected single retransmission of KV Blocks in error in previous transmission cycle and with sample interleaving.

It is possible to see that the performance of KV/32-ary PAM with first order error correction (FEC), single retransmission of KV blocks in error in previous transmission cycle and sample interleaving significantly performance better than the KV/32-ary PAM with first order error correction (FEC) only. This system shows for average Eb/N0<10 dB, the proposed KV/32-ary PAM with first order FEC, single selected KV block transmission in error and sample interleaving reaches a BER performance of <10⁻⁷.

The systems were also compared subjectively with real digital speech and transmission of a video frame at various values of Average Eb/N0. FIG. 10 illustrates the performance of JPEG picture for different conditions.

It is possible to see that the performance of KV/32-ary PAM with first order error correction (FEC), single retransmission of KV blocks in error in previous transmission cycle and sample interleaving significantly performance better than the KV/32-ary PAM with first order error correction (FEC) only. This system shows for average Eb/N0<10 dB, the proposed KV/32-ary PAM with first order FEC, single selected KV block transmission in error and sample interleaving reaches a BER performance of <10^{-7.}

The systems were also compared subjectively with real digital speech and transmission of a video frame at various values of Average Eb/N0. FIG. 10 illustrates the performance of JPEG picture for different conditions.

In FIG. 10, the top two pictures are original as well as reconstructed with first order FEC, single retransmission of KV Blocks in error and sample dispersion. The bottom pictures are recovered at 17 dB without sample dispersion and without retransmission on the left and at 12 dB without sample dispersion and without retransmission on the right. Since the average BER at these EB/N0s is very insignificant for the KV/32-ary PAM with first order FEC and single retransmission of KV block in error and sample dispersion, there is no difference between the original and the recovered picture.

IV. E. Summary and Conclusion

In this paper, we proposed a novel KV transform technique and its performance is compared with that of conventional system using PAM modulation technique under Rayleigh fading noise channel. The intention is to demonstrate a method of using error correction for handling multi-path interference in MANETs particularly for indoor and outdoor applications. Multi-path interference in outdoor environment typically reduces the Average Eb/N0 for a small duration due to objects and in indoor environment it tends to exhibit flat fading due to metallic building due to reflections of waves that cause both amplitude distortions and random time delays of waves being received. Under these circumstances, the average Eb/No tends to be very small in the order <10 dB. The proposed system enables recovery of data under these circumstances as shown in FIGS. 8-10.

As a future research issue, the KV transform coding technique is being enhanced to correct two samples in error out of four samples using a system of equations with understanding how any pair of coefficient samples appears to have errors.

### REFERENCES

[1]. D. Huong, R. A. Iltis, “Performance Evaluation of Multi-hop CSMA/CA Networks in Fading Environments”, IEEE Transactions on Communications, Vol. 56, NO. 1, January 2008, pp 112-123.
[2]. C. W. Tsai, J. L. Wu, “On Constructing the Huffman-Code-based Reversible Variable Length Codes”, IEEE Transactions on Communications Theory, Vol. 49, No. 8, September 2001, pp 1506-1509.
[3]. Wilson, Stephen G., “Digital Modulation and Coding”, Englewood Cliffs, N.J.: Prentice-Hall, 1996.
[4]. S. Lin and D. J. Costello, Jr., “Error Control Coding: Fundamentals and Applications”, Prentice Hall: Englewood Cliffs, N.J., 1983.
[5]. R. Zhou, R. L. Bidan, A. Goalic, “Low Complexity High Rate Reed-Solomon Block Turbo Code”, IEEE Transactions on Communications, Vol. 55, No. 9, September 2007, pp 1656-1660.
[6]. C. M. Lee, Y. T. Su, L. D. Jeng, “Performance Analysis of Block Codes in Hidden Markov Channels”, IEEE Transactions on Communications, Vol. 56, NO. 1, January 2008, pp 1-4.
[7]. U. Charash, “Reception through Nakagami Fading Multi-path Channels with Random Delays”, IEEE Transactions on Communications, Vol. 27, April 1979, pp 657-670.
[8] D. R. Vaman, “Management and Control of Highly Mobile Ad hoc Wireless Network for supporting Multi-Service QoS assured Applications” Proceedings of the Wireless Conference,—Invited Paper, University of Helsinki, Finland, May 22, 2006.
[9] D. R. Vaman, “Management and Control of Highly Mobile Ad hoc Wireless Network for supporting Multi-Service QoS assured Applications”, Invited Workshop, May 19-21, 2006, Nokia—University Consortium, Kokkola, Finland.
[10] C. R. Lin and M. Gerla, “Adaptive clustering for mobile wireless networks”, IEEE Journal of Selected Area Communications, vol. 15, pp. 1265-1275, September 1997.
[11] P. J. Crepeo, “Uncoded and Coded Performance of M-ary Orthogonal Signaling and DPSK in Nakagami Fading Channels”, IEEE Transactions on Communications, Vol. 40, March 1992, pp 487-493.
[12] John G. Proakis, “Digital Communications”, 4h Edition, McGraw-Hill Publishing Company, 2000.
[13] R. N. Mcdonough and A. D. Whalen, “Detection of Signals in Noise”, 2^{nd} edition, Academic Press, 1995.

### Appendix A: Principles of KV Transform Coding

We assume that the input source is in digital form. The data sequence from a source is used to create discrete samples which are used as the input to the KV transform. It is important to know that a set of input bits (b=1, 2, 3, 4, 5, 6 . . . ) which form a set of discrete samples will have a finite set of values. We represent these discrete samples as an input vector of n elements:

[s1 s2 s3 s4 . . . sn] (A-1)

Then, we construct a set of orthogonal basis functions using the fundamental basis function:

$$Φ ( t ) = \{ \begin{matrix}1 & 0 \leq t < \frac{1}{2} \\ - 1 & \frac{1}{2} \leq t < 1 \\ 0 & otherwise\end{matrix} \qquad ( A \text{-} 2 )$$

For constructing the other orthogonal basis functions, we use the following steps of first time-shifting and then time-scaling operations as shown below:

$$\begin{matrix}Φ ( t ) \to Φ ( {2}^{j} t - i ) \\ Φ ( t ) {\to }^{t \to t - i} Φ ( t - i ) {\to }^{t \to {2}^{{j}_{t}}} Φ ( {2}^{j} t - i ) \\ {Φ}_{i}^{j} ( t ) = Φ ( {2}^{j} t - i )\end{matrix} \qquad ( A \text{-} 3 )$$

where i=0, 1,2, . . . ,2 ^{j}−1; j=0,1,2, . . . ,k; k=log₂ n−1; and n is the number of 2^{m} digits (or samples) in a data sequence, where m=1, 2, 3, . . .

Each basis function is a vector of length n. For transformation on n input samples, there will be n normalized orthogonal vectors. The latter can be easily obtained by simply multiplying each orthogonal vector by a scalar

$$\sqrt{\frac{n}{{2}^{j}}} .$$

Collectively, they form n×n matrix and used to transform the input vector of n samples into coefficient samples. Using the transformation in (2), the following orthogonal basis functions are computed:

The first 2 orthogonal basis functions:

U(t)={1, 1, 1, . . . ), Φ₀⁰(t)=Φ(t) (A-4)

The first 4 orthogonal basis functions:

U(t), Φᵢ₌₀^{j=0}(t), Φ_{i=0,1}^{j=1}(t) (A-5)

The first 8 orthogonal basis functions:

U(t), Φᵢ₌₀^{j=0}, Φ_{i=0,1}^{j=1}, Φ_{i=0,1,2,3}^{j=2}(t) (A-6)

The first 16 orthogonal basis functions:

U(t), Φᵢ₌₀^{j=0}(t), Φ_{i=0,1}^{j=1}(t), Φ_{i=0,1,2,3}^{j=2}(t), Φ_{i=0,1, . . . 7}^{j=3}(t) (A-7)

The first 32 orthogonal basis functions:

U(t), Φᵢ₌₀^{j=0}(t), Φ_{i=0,1}^{j=1}(t), Φ_{i=0,1,2,3}^{j=2}(t), Φ_{i=0,1, . . . 7}^{j=3}(t), Φ_{i=0,1, . . . 15}^{j=4}(t) (A-8)

Thus, it is possible to create any size orthogonal basis functions. It is important to note that the basis functions are created such that higher set of orthogonal basis functions are appended to the lower set of orthogonal basis functions.

The dot product of the input vector of n discrete samples and the normalized orthogonal basis function matrix generates n KV coefficient samples:

[c1 c2 c3 c4 . . . cn] (A-9)

These n KV coefficient samples are transformed into a set of samples {c1+c2; c1−c2; c3; c4} for transmission.

At the receiving side, using the transformed samples, we recover the original coefficient samples {c1, c2, c3 and c4}. The product of these coefficient samples and the n×n orthogonal basis function matrix generates an n×n decision matrix:

$$[ \begin{matrix}D 11 & D 12 & D 13 & D 14 & … & D 1 n \\ D 21 & D 22 & D 23 & D 24 & … & D 2 n \\ … & … & … & & & \\ Dn 1 & Dn 2 & Dn 3 & … & & Dnn\end{matrix} ] \qquad ( A \text{-} 10 )$$

The original discrete samples are recovered by adding each vertical elements of the n×n decision matrix:

[D11+D21+D31+ . . . +Dn1]=s1

[D12+D22+D32+ . . . +Dn2]=s2

[D1n+D2n+D3n+ . . . +Dnn]=sn (A-11)

Each sample is then used to create the digital information and sent to the receiving side. The error correction for the samples is done prior to inverse KV transmission.

1. Claims the novel concept of Koay-Vaman Transform Coding that is efficient and simple for implementation for forward error correction.

2. Claims that KV transform of any size of discrete samples constructed from digital inputs shall be corrected and operated to handle burst noise channel that contain multi-path interference.

3. Claims that KV transform operates at very low Eb/N0 and recover data at very low Bit Error Rates.

4. Claims that KV transform technique operates with any modulation technique and not limited to Pulse Amplitude Modulation.

5. Claims teachings of KV operation in detail integrated with single selected retransmission and sample interleaving.

6. Claims that KV Transform System is applicable to all wireless network architectures, diffusion centers in sensor networks and where congestion needs to be handled by dropping message units and reconstructing the dropped messages at the destination.
